(19) United States
(12) Patent Application Publication
(10) Pub. No.: US 2026/0150621 A1
(43) Pub. Date: May 28, 2026

(54) VACUUM ACTUATOR, METHOD OF MANUFACTURING VACUUM ACTUATOR, AND ROTARY FEEDTHROUGH

(71) Applicant: Nabtesco Corporation, Tokyo (JP)

(72) Inventors: Koji KUBOTA, Tokyo (JP); Kenta OHASHI, Ibaraki (JP); Naoki OGATA, Ibaraki (JP)

(21) Appl. No.: 19/348,517

(22) Filed: Oct. 2, 2025

(30) Foreign Application Priority Data
Oct. 4, 2024 (JP) 2024-174924

(51) Int. Cl. H01L 21/687

(52) U.S. Cl. CPC H10P 72/7602

(57) ABSTRACT

A vacuum actuator of the present disclosure includes: a partition wall separating a vacuum-side space from an atmosphere-side space; a shaft member penetrating the partition wall, the shaft member transmitting a drive force; a sealing member provided on the partition wall, the sealing member sliding against a sliding surface formed on an outer periphery of the shaft member, and the sealing member sealing between the vacuum-side space and the atmosphere-side space; and a friction-reducing portion formed on the sliding surface.

### CROSS-REFERENCE TO RELATED APPLICATIONS

This application is based on and claims the benefit of priority from Japanese Patent Application Serial No. 2024-174924 (filed on Oct. 4, 2024), the contents of which are hereby incorporated by reference in its entirety.

### TECHNICAL FIELD

The present disclosure relates to a vacuum actuator, a method of manufacturing a vacuum actuator, and a rotary feedthrough.

### BACKGROUND

In the manufacture of flat panel displays (FPDs) such as liquid crystal displays and organic EL displays, or in the manufacture of semiconductor devices, substrates are moved to a processing section of an apparatus in a vacuum such as a vacuum chamber for processing. As this point, used is a vacuum actuator, such as a rotary feedthrough, for introducing driving force into the chamber from a drive source disposed outside the vacuum.

In such vacuum actuators, it is required to maintain sealing on both sides of a partition wall in order to preserve the vacuum, while also transmitting the driving force from the outside of the chamber to the inside. Accordingly, vacuum actuators are required to have vacuum sealing at sliding surfaces. To ensure sealing performance at the sliding surfaces when exposed to a vacuum atmosphere, it is known to use lubricants such as polytetrafluoroethylene (PTFE). For example, Japanese Patent Application Publication No. Hei 11-166632 discloses application of an oil-repellent resin, such as polytetrafluoroethylene, to an outer peripheral surface of a dust lip of a sealing member.

However, when forming a solid lubricating layer made of polytetrafluoroethylene (PTFE) on the sliding surface, a baking process is required. Due to the risk that the resin may deteriorate during the baking process and fail to maintain the sealing performance, it was not possible to form the solid lubricating layer made of PTFE on sealing members made of resins or the like.

### SUMMARY

A vacuum actuator according to an aspect of the present disclosure includes: a partition wall separating a vacuum-side space from an atmosphere-side space; a shaft member penetrating the partition wall, the shaft member transmitting a drive force; a sealing member provided on the partition wall, the sealing member sliding against a sliding surface formed on an outer periphery of the shaft member, and the sealing member sealing between the vacuum-side space and the atmosphere-side space; and a friction-reducing portion formed on the sliding surface. This configuration can solve the above-described drawbacks.

With this configuration, friction in the sealing portion where the sealing member contacts the sliding surface at the boundary between the vacuum and atmospheric environments can be reduced by the friction-reducing portion. For example, friction between the sliding surface and the sealing member that contacts the sliding surface along the circumferential direction of the shaft member can be reduced. Furthermore, the friction-reducing portion suppresses temperature rise at the sealing portion. As a result, the vacuum sealing at the sealing portion can be maintained. Moreover, by forming the friction-reducing portion on the sliding surface, the coefficient of friction between the sealing member and the sliding surface at the sealing portion is reduced compared to a configuration without the friction-reducing portion. This prevents, for example, wear of the resin-based sealing member caused by the metal shaft member. In this way, it is possible to prevent both the generation of particles which may serve as contamination sources for the vacuum-side space and deterioration in the sealing performance. Here, the vacuum-side space may be defined as a space having a pressure of 10 Pa or less.

In the above vacuum actuator, the friction-reducing portion may serve as a transfer-source supply that supplies a transfer source, the transfer source reducing friction by transferring to the sealing member that slides.

In the above vacuum actuator, the friction-reducing portion may be formed on the sliding surface with a thickness of 25 μm or greater.

In the above vacuum actuator, surface roughness of the sliding surface on which the friction-reducing portion is formed may be Rz 1.6 μm or less.

In the above vacuum actuator, hardness of the sliding surface on which the friction-reducing portion is formed may be Vickers hardness (HV) 544 or greater.

In the above vacuum actuator, the friction-reducing portion may include a solid lubricant layer containing a solid lubricant, and a semi-solid lubricant layer formed between the surface of the solid lubricant layer and the sealing member.

In the above vacuum actuator, the solid lubricant layer may include a solid lubricant having a particle size of 10 μm or less.

In the above vacuum actuator, the solid lubricant may include polytetrafluoroethylene.

In the above vacuum actuator, the shaft member may be formed of nitrided stainless steel, chromium-molybdenum steel, or carbon steel.

In the above vacuum actuator, the sealing member may include a metal ring that surrounds the outer periphery of the shaft member along the sliding surface, and a seal lip portion that linearly contacts the sliding surface.

A method of manufacturing a vacuum actuator, includes: a friction-reducing portion formation step of forming a friction-reducing portion on a sliding surface on an outer periphery of an shaft member, the shaft member penetrating a partition wall that separates a vacuum-side space from an atmosphere-side space; and an assembly step of assembling a sealing member such that the sealing member contacts the sliding surface on which the friction-reducing portion has been formed.

In this configuration, a vacuum actuator capable of reducing the coefficient of friction can be manufactured by first forming the friction-reducing portion having predetermined properties and then assembling the sealing member.

In the above method of manufacturing a vacuum actuator, the friction-reducing portion formation step may include a preparation step in which the sliding surface on which the friction-reducing portion is to be formed is process to have a surface roughness of Rz 1.6 μm or less.

In the above method of manufacturing a vacuum actuator, the friction-reducing portion formation step includes: a solid lubricant layer material application step of applying a raw material for a solid lubricant layer to the friction-reducing portion; a solid lubricant layer firing step of firing the applied raw material. The friction-reducing portion formation step forms the friction-reducing portion having the solid lubricant layer including the solid lubricant.

In the above method of manufacturing a vacuum actuator, a firing temperature in the solid lubricant layer firing step may be in the range of 200° C. to 250° C.

In the above method of manufacturing a vacuum actuator, the friction-reducing portion formation step may include a semi-solid lubricant application step in which the semi-solid lubricant layer is formed between the surface of the solid lubricant layer and the sealing member. The consistency of the semi-solid lubricant layer applied in the semi-solid lubricant application step may be higher than the consistency of the raw material of the solid lubricant layer applied in the solid lubricant layer material application step.

A rotary feedthrough according to another aspect of the disclosure includes: a partition wall separating a vacuum-side space from an atmosphere-side space; a shaft member penetrating the partition wall, the shaft member transmitting a drive force; an input unit disposed in the atmosphere-side space and configured to input a drive force to the shaft member; a sealing member provided on the partition wall, the sealing member sliding against a sliding surface formed on an outer periphery of the shaft member, and the sealing member sealing between the vacuum-side space and the atmosphere-side space; and a friction-reducing portion formed on the sliding surface. The friction-reducing portion serves as a transfer-source supply that supplies a transfer source, the transfer source reducing friction by transferring to the sealing member that slides. The friction-reducing portion includes a solid lubricant layer containing a solid lubricant, and a semi-solid lubricant layer formed between the surface of the solid lubricant layer and the sealing member. The input unit outputs, to the shaft member, rotation of a drive source that is disposed in the atmosphere-side space and generates a rotational force. The shaft member transmits a rotational drive force to the vacuum-side space.

With this configuration, in the rotary feedthrough that introduces the rotational drive force from the atmosphere-side space into the vacuum-side space, it is possible to prevent deterioration in sealing performance at the sealing portion during transmission of the rotational drive force to the vacuum-side space. While maintaining this state, solid lubricant contained in the solid lubricant layer can be transferred as transfer particles to the sealing member, thereby allowing the solid lubricant to adhere to the sealing member. As a result, the coefficient of friction at the sealing portion can be reduced through the combined effect of the solid lubricant layer formed on the sliding surface and the solid lubricant transferred to the seal member. By reducing the coefficient of friction at the sealing portion, temperature rise at the sealing portion can be suppressed. By reducing the coefficient of friction at the sealing portion, wear of the sealing member can be prevented. By preventing wear of the sealing member, generation of particles, which may serve as contamination sources, can be suppressed. Furthermore, the semi-solid lubricant layer enhances these effects. Consequently, the durability of the rotary feedthrough can be improved while maintaining the vacuum sealing performance. Additionally, it is possible to prevent an increase in torque of the rotary feedthrough during transmission of the rotational drive force to the vacuum-side space.

A rotary feedthrough according to still yet another aspect of the disclosure includes: a partition wall separating a vacuum-side space from an atmosphere-side space; a shaft member penetrating the partition wall, the shaft member transmitting a drive force; an input unit disposed in the atmosphere-side space and configured to input a drive force to the shaft member; a sealing member provided on the partition wall, the sealing member sliding against a sliding surface formed on an outer periphery of the shaft member, and the sealing member sealing between the vacuum-side space and the atmosphere-side space; and a friction-reducing portion formed on the sliding surface. The friction-reducing portion serves as a transfer-source supply that supplies a transfer source, the transfer source reducing friction by transferring to the sealing member that slides. The friction-reducing portion includes a solid lubricant layer containing a solid lubricant, and a semi-solid lubricant layer formed between the surface of the solid lubricant layer and the sealing member. The input unit outputs, to the shaft member, rotation of a drive source that is disposed in the atmosphere-side space and generates a rotational force. The shaft member transmits a rotational drive force to the vacuum-side space. The input unit includes: a case; an internal gear provided in the case and having internal teeth; an oscillating gear having external teeth meshing with the internal teeth of the internal gear, the oscillating gear being configured to be oscillatorily rotated; a crankshaft having an eccentric portion that rotatably supports the oscillating gear, the crankshaft transmitting a rotational force of a drive source to the oscillating gear; a carrier configured to receive the rotational force from the oscillating gear and serve as an output portion tat outputs the rotational force to the shaft member.

With this configuration, in the rotary feedthrough that introduces the rotational drive force from the atmosphere-side space into the vacuum-side space via an oscillating transmission, it is possible to prevent deterioration in sealing performance at the sealing portion during transmission of the rotational drive force to the vacuum-side space. While maintaining this state, solid lubricant contained in the solid lubricant layer can be transferred as transfer particles to the sealing member, thereby allowing the solid lubricant to adhere to the sealing member. As a result, the coefficient of friction at the sealing portion can be reduced through the combined effect of the solid lubricant layer formed on the sliding surface and the solid lubricant transferred to the seal member. By reducing the coefficient of friction at the sealing portion, temperature rise at the sealing portion can be suppressed. By reducing the coefficient of friction at the sealing portion, wear of the sealing member can be prevented. By preventing wear of the sealing member, generation of particles, which may serve as contamination sources, can be suppressed. Furthermore, the semi-solid lubricant layer enhances these effects. Consequently, the durability of the rotary feedthrough and the oscillating transmission can be improved while maintaining the vacuum sealing performance. Additionally, it is possible to prevent an increase in torque of the rotary feedthrough and the oscillating transmission during transmission of the rotational drive force to the vacuum-side space.

A robot according to another aspect of the disclosure includes: a partition wall separating a vacuum-side space from an atmosphere-side space; a shaft member penetrating the partition wall, the shaft member transmitting a drive force; an input unit disposed in the atmosphere-side space and configured to input a drive force to the shaft member; a sealing member provided on the partition wall, the sealing member sliding against a sliding surface formed on an outer periphery of the shaft member, and the sealing member sealing between the vacuum-side space and the atmosphere-side space; and a friction-reducing portion formed on the sliding surface. The friction-reducing portion serves as a transfer-source supply that supplies a transfer source, the transfer source reduces friction by transferring to the sealing member that slides. The friction-reducing portion includes a solid lubricant layer containing a solid lubricant, and a semi-solid lubricant layer formed between the surface of the solid lubricant layer and the sealing member. The input unit outputs, to the shaft member, rotation of a drive source that is disposed in the atmosphere-side space and generates a rotational force. The shaft member transmits a rotational drive force to the vacuum-side space.

With this configuration, in the robot that introduces the rotational drive force from the atmosphere-side space into the vacuum-side space via an oscillating transmission, it is possible to prevent deterioration in sealing performance at the sealing portion during transmission of the rotational drive force to the vacuum-side space. While maintaining this state, solid lubricant contained in the solid lubricant layer can be transferred as transfer particles to the sealing member, thereby allowing the solid lubricant to adhere to the sealing member. As a result, the coefficient of friction at the sealing portion can be reduced through the combined effect of the solid lubricant layer formed on the sliding surface and the solid lubricant transferred to the seal member. By reducing the coefficient of friction at the sealing portion, temperature rise at the sealing portion can be suppressed. By reducing the coefficient of friction at the sealing portion, wear of the sealing member can be prevented. By preventing wear of the sealing member, generation of particles, which may serve as contamination sources, can be suppressed. Furthermore, the semi-solid lubricant layer enhances these effects. Consequently, the durability of the robot can be improved while maintaining the vacuum sealing performance. Additionally, it is possible to prevent an increase in torque of the rotary feedthrough and the oscillating transmission in the robot during transmission of the rotational drive force to the vacuum-side space.

### ADVANTAGEOUS EFFECTS

It is possible to provide a vacuum actuator capable of maintaining vacuum sealing while reducing friction, a method of manufacturing the vacuum actuator, and a rotary feedthrough.

### BRIEF DESCRIPTION OF THE DRAWINGS

FIG. 1 is a partially sectional side view showing a rotary feedthrough according to a first embodiment of the present disclosure.

FIG. 2 is an enlarged sectional view showing a sealing portion of the rotary feedthrough according to the first embodiment of the disclosure.

FIG. 3 is a sectional view showing a rotary input section of the rotary feedthrough according to the first embodiment of the disclosure.

FIG. 4 is a sectional view along line IV-IV in FIG. 3.

FIG. 5 is a flowchart illustrating a method of manufacturing the rotary feedthrough according to the first embodiment of the disclosure.

FIG. 6 is a schematic view showing a vacuum processing apparatus equipped with a rotary feedthrough according to a second embodiment of the disclosure.

FIG. 7 is a schematic side view showing a substrate transfer robot equipped with the rotary feedthrough according to the second embodiment of the disclosure.

### DESCRIPTION OF THE EMBODIMENTS

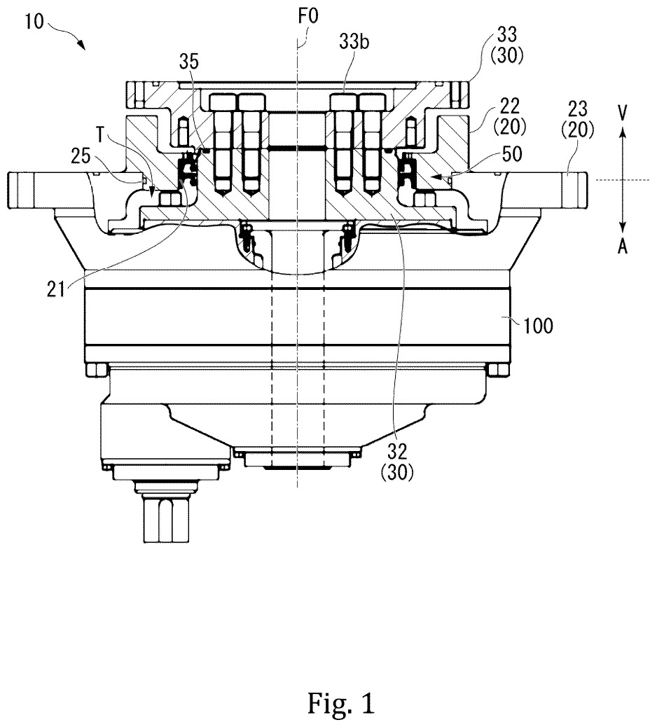

A rotary feedthrough relating to a first embodiment of the disclosure will be described with reference to the accompanying drawings. The rotary feedthrough is one example of a vacuum actuator. FIG. 1 is a partially sectional side view showing the rotary feedthrough of the embodiment. In FIG. 1, reference numeral 10 denotes the rotary feedthrough.

As shown in FIG. 1, the rotary feedthrough 10 according to the embodiment includes a seal partition wall 20, a rotating member 30, a seal mechanism 50, and a rotation input unit 100. The rotating member 30 is an example of a shaft member. The rotation input unit 100 is an example of any one of an input portion, a transmission, or a speed reducer. The seal partition wall 20 is an example of a partition wall.

The seal partition wall 20 is, for example, a partition wall of a vacuum chamber. The seal partition wall 20 separates an upper space and a lower space in FIG. 1. In FIG. 1, the seal partition wall 20 separates an atmospheric-side space A (first space) situated below the seal partition wall 20, and a vacuum-side space V (second space) situated above the seal partition wall 20. The atmosphere-side space A is, for example, maintained at atmospheric pressure. The vacuum-side space V is, for example, maintained in a vacuum atmosphere or at a reduced-pressure relative to the atmosphere-side space A. The vacuum-side space V may be reduced to a pressure of approximately 10 Pa or lower. For example, the vacuum-side space V may be reduced to a pressure of approximately 10⁻⁵ Pa. Alternatively, the vacuum-side space V may be reduced to a pressure of approximately 10⁻⁶ Pa.

The seal partition wall 20 seals (airtightly isolates) the atmosphere-side space A and the vacuum-side space V so as to prevent the migration of gas or the like between the atmosphere-side space A and the vacuum-side space V. Although not shown in the drawings, the seal partition wall 20 may extend outward in the left and right directions of FIG. 1. The rotation input unit 100 is disposed in the atmosphere-side space A below the seal partition wall 20.

The through-hole 21 is formed in the seal partition wall 20. The seal partition wall 20 includes a penetration member 22 in which the through-hole 21 is formed, and a wall portion 23 that separates the atmosphere-side space A from the vacuum-side space V. The portion between the penetration member 22 and the wall portion 23 may be sealed. In this case, a sealing member 25 such as an O-ring is disposed between the penetration member 22 and the wall portion 23. A rotating member 30 is inserted in the through-hole 21.

The rotating member 30 is a rotation-transmitting shaft configured to impart rotational force to a device disposed in the vacuum chamber. The rotating member 30 penetrates the seal partition wall 20 that separates the interior and exterior of the vacuum chamber. The rotating member 30 extends in the through-hole 21 from the vacuum-side space V inside the vacuum chamber to the atmosphere-side space A outside the vacuum chamber.

As shown in FIG. 1, the rotating member 30 has a rotational axis F0 that extends in upper and lower directions. The rotating member 30 is rotationally driven by the rotation input unit 100. The rotating member 30 is connected to the rotation input unit 100 in the atmosphere-side space A below the seal partition wall 20. The rotational axis F0 of the rotating member 30 coincides with the rotational axis F0 of a carrier 204 of the rotation input unit 100, which will be described later. The rotating member 30 is surrounded by the seal partition wall 20 in the through-hole 21. An annular space T is formed between the rotating member 30 and the seal partition wall 20. The annular space T includes at least the interior of the through-hole 21.

As shown in FIG. 1, the rotating member 30 includes a connection member 32 disposed adjacent to the atmosphere-side space A, and a rotating end portion 33 disposed adjacent to the vacuum-side space V rather than the seal partition wall 20. The connection member 32 is connected to the rotation input unit 100 in the atmosphere-side space A. The connection member 32 protrudes into the vacuum-side space V along the rotational axis F0 beyond the seal partition wall 20. The connection member 32 and the rotating end portion 33 are fastened together by bolts 33b that extend parallel to the rotational axis F0. The portion between the connection member 32 and the rotating end portion 33 is sealed. A sealing member 35, such as an O-ring, is disposed between the connection member 32 and the rotating end portion 33.

The connection member 32 is received in the through-hole 21 in a direction along the rotational axis F0. A seal mechanism 50 is disposed between the connection member 32 and the through-hole 21. The connection member 32 includes, on its outer peripheral surface 30S, a friction-reducing portion 34 that contacts the seal mechanism 50. A region of the outer peripheral surface 30S that contacts the seal mechanism 50 serves as a sliding surface 30SS. The friction-reducing portion 34 is formed on the sliding surface 30SS of the connection member 32. The seal mechanism 50 seals a portion between the atmosphere-side space A and the vacuum-side space V. The friction-reducing portion 34 and the seal mechanism 50 will be described later in detail. The outer periphery of the rotating end portion 33 faces an inner periphery of the penetration member 22 at a position closer to the vacuum-side space V than the seal mechanism 50 in the direction along the rotational axis F0.

The rotation input unit 100 is configured as a speed reducer, as will be described later. Hereinafter, the rotation input unit 100 may be referred to as the speed reducer 100. The connection member 32 is connected to the carrier 204 of the speed reducer 100, as will be described later. The seal partition wall 20 is formed integrally with a case 202 and the wall portion 23 of the speed reducer 100, as will be described later. The case 202 is an example of an outer cylinder.

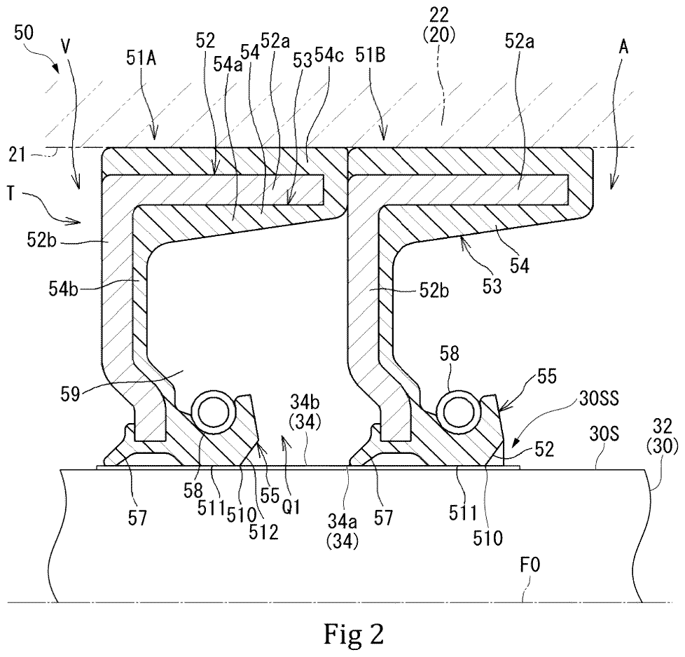

FIG. 2 is an enlarged sectional view showing the seal mechanism 50 according to the embodiment. The seal mechanism 50 partitions the annular space T formed between the rotating member 30 and the seal partition wall 20 in a sealed state. In the through-hole 21, the seal mechanism 50 partitions the atmosphere-side space A and the vacuum-side space V. The seal mechanism 50 partitions the through-hole 21 in the direction of the axis F0 (rotational axis). As shown in FIG. 2, the seal mechanism 50 of the embodiment includes a sealing device 51A and a sealing device 51B. Each of the sealing devices 51A and 51B is an example of a sealing member. The sealing device 51A may be referred to as a first sealing device 51A. The sealing device 51B may be referred to as a second sealing device 51B. In this case, the sealing device 51A is an example of a first sealing member. The sealing device 51B is an example of a second sealing member.

The sealing device 51A and the sealing device 51B have the same shape. The sealing device 51A and the sealing device 51B are disposed adjacent to each other in the direction along the rotational axis F0. The sealing device 51A and the sealing device 51B are arranged in parallel in the direction along the rotational axis F0.

In the embodiment, the seal mechanism 50 is configured as a two-stage seal that includes the sealing device 51A and the sealing device 51B, in order to enhance sealing performance. It is also possible for the seal mechanism 50 to be configured as a single-stage seal that includes only the sealing device 51A. Alternatively, the seal mechanism 50 may be configured as a multi-stage seal in which three or more sealing devices 51A are arranged in series.

In FIG. 2, the configuration of the sealing device 51B is the same as that of the sealing device 51A, and therefore the same reference numerals are used, and a detailed description may be omitted.

The sealing device 51A includes a core metal 52 and a hermetical sealing member 53. The core metal 52 is an example of a metal ring. The core metal 52 is made of metal. The core metal 52 is formed in an annular shape that extends circumferentially around the rotational axis F0. The core metal 52 is formed by press-working a steel sheet such as SPCC. The sectional shape of the core metal 52 in a radial direction with respect to the rotational axis F0 is L-shaped.

The core metal 52 includes a first cylindrical portion 52a and a first annular portion 52b. The first cylindrical portion 52a has a cylindrical shape that extends parallel to an inner circumferential surface of the through-hole 21. The first annular portion 52b extends radially inward from one end of the first cylindrical portion 52a. The hermetic sealing member 53 is formed from an elastic material such as rubber. The hermetic sealing member 53 is formed by being bonded to the surface of the core metal 52 through vulcanization adhesion.

The hermetic sealing member 53 includes a base body 54, a seal lip portion 55, and an auxiliary lip portion 57. The base body 54 covers an outer circumferential surface of the first cylindrical portion 52a of the core metal 52. The base body 54 extends around and covers an end surface of the first cylindrical portion 52a that faces the atmospheric-pressure space A. The base body 54 covers an inner circumferential surface of the first cylindrical portion 52a. Further, the base body 54 covers a side surface of the first annular portion 52b that faces the atmospheric-pressure space A. The base portion 54 is bonded to the outer circumferential surface, the end surface, and the inner circumferential surface of the first cylindrical portion 52a, and to the side surface of the first annular portion 52b.

The base portion 54 includes a second cylindrical portion 54a that covers the inner circumferential surface of the first cylindrical portion 52a, a second annular portion 54b that covers an inner side surface of the first annular portion 52b, and a third cylindrical portion 54c that covers the outer circumferential surface of the first cylindrical portion 52a of the core metal 52. The second cylindrical portion 54a, the second annular portion 54b, and the third cylindrical portion 54c are integrally and continuously formed. The base body 54 covers the surface of the core metal 52, except for a surface thereof that faces the vacuum-side space V.

The third cylindrical portion 54c is in contact with the inner circumferential surface of the through-hole 21. The core metal 52 is press-fitted into the through-hole 21 via the third cylindrical portion 54c of the base body 54. Accordingly, the sealing device 51A is fixed to the through-hole 21. The hermetic sealing member 53 includes a recessed portion 59 that is annular around the rotational axis F0. The annular recessed portion 59 is defined by the second cylindrical portion 54a, the second annular portion 54b, and the seal lip portion 55.

Similar to the seal lip portion 55, the auxiliary lip portion 57 extends inward along the rotational axis F0 from an inner circumferential end of the first annular portion 52b. The auxiliary lip portion 57 extends toward the vacuum-side space V from the inner circumferential end of the first annular portion 52b of the core metal 52 at its base end. The auxiliary lip portion 57 gradually decreases in diameter around the rotational axis F0 toward the vacuum-side space V. A distal end of the auxiliary lip portion 57 is in contact with the sliding surface 30SS of the rotating member 30. The distal end of the auxiliary lip portion 57 slides against the sliding surface 30SS of the rotating member 30.

The seal lip portion 55 is an annular member that extends toward the atmosphere-side space A from the inner circumferential end of the first annular portion 52b of the core metal 52 at its base end. The seal lip portion 55 extends from the inner circumferential end of the first annular portion 52b in the radially inward direction of the rotational axis F0. A main seal lip 510 is formed on an inner peripheral surface of the seal lip portion 55. A sectional shape of the main seal lip 510 has a corner. The main seal lip 510 is formed at a vertex formed by a vacuum-space-side inclined surface 511 and an atmosphere-space-side inclined surface 512.

The main seal lip 510 is in contact with the sliding surface 30SS of the rotating member 30. The main seal lip 510 slides against the sliding surface 30SS of the rotating member 30. The vacuum-space-side inclined surface 511 extends from the main seal lip 510 toward the vacuum-side space V. The vacuum-space-side inclined surface 511 gradually increases in diameter around the rotational axis F0 toward the vacuum-side space V.

The atmosphere-space-side inclined surface 512 extends from the main seal lip 510 toward the atmosphere-side space A. The atmosphere-space-side inclined surface 512 gradually increases in diameter around the rotational axis F0 toward the atmosphere-side space A. A vertex formed by the vacuum-space-side inclined surface 511 and the atmosphere-space-side inclined surface 512 defines a corner of the main seal lip 510 in its sectional shape.

A garter spring 58 is disposed at a position adjacent to an outer peripheral surface of the seal lip portion 55. The garter spring 58 compresses and presses the seal lip portion 55 inward in the radial direction of the rotational axis F0. By compressing and pressing the seal lip portion 55 radially inward, the garter spring 58 enhances the sealing performance. The garter spring 58 is an example of the metal ring.

The seal lip portion 55 is in contact with the sliding surface 30SS of the rotating member 30 so as to be slidable thereon. By sliding between the seal lip portion 55 and the sliding surface 30SS of the rotating member 30, the pressure of the atmosphere-side space A seals between the atmosphere-side space A and the vacuum-side space V, thereby preventing gas from leaking from the atmosphere-side space A into the vacuum-side space V through the region between the rotating member 30 and the through-hole 21.

As described above, the seal lip portion 55 extends toward the atmosphere-side space A from its base end situated at the inner circumferential end of the first annular portion 52b of the core metal 52. Thus, the seal lip portion 55 is configured such that its end facing the atmosphere-side space A is movable outward in the radial direction around the rotational axis F0, with its end adjacent to the vacuum-side space V serving as a fulcrum.

When the rotating member 30 is inserted into the inner circumference of the seal lip portion 55, the end of the seal lip portion 55 that faces the atmosphere-side space A moves outward in the radial direction of the rotational axis F0. As to the seal lip portion 55, the end of the seal lip portion 55 facing the atmosphere-side space A moves radially outward, whereby the end of the seal lip portion 55 facing the atmosphere-side space A and the main seal lip 510 elastically deform such that their diameters slightly increase.

The main seal lip 510 in the seal lip portion 55, in a free state, is formed to have a predetermined inner diameter smaller than the outer diameter of the rotating member 30. FIG. 2 illustrates a state in which the rotating member 30 is inserted along the inner circumference of the seal lip portion 55, and the main seal lip 510 is elastically deformed and brought into contact with the sliding surface 30SS of the rotating member 30.

The sealing device 51B is arranged adjacent to the sealing device 51A on the atmosphere-side space A side. In the sealing device 51B, the side surface of the first annular portion 52b of the core metal 52 facing the vacuum-side space V abuts and contacts the base body 54 that covers the end surface of the first cylindrical portion 52a of the sealing device 51A facing the atmosphere-side space A. Thus, an annular space Q1 is formed by the recessed portion 59 of the sealing device 51A, the first annular portion 52b of the sealing device 51B, and the sliding surface 30SS of the rotating member 30.

The space Q1 can serve as a lubricant retention space. A highly viscous lubricant may be used as the lubricant retained in the space Q1. Preferably, the lubricant is grease. The lubricant retained in the space Q1 may be supplied to a part of the sliding surface where the main seal lip 510 of the sealing device 51A contacts the sliding surface 30SS of the rotating member 30. This enhances the lubricity of the sliding surface and prevents wear thereof. As a result, the sealing performance of the sealing device 51A is maintained over a prolonged period. In the sealing mechanism 50, the main seal lip 510 contacts the friction-reducing portion 34 formed on the sliding surface 30SS of the connection member 32. The portions that slide in contact with each other, namely, the seal lip portion 55 and the friction-reducing portion 34 are referred to as a sealing portion. In some cases, the sealing portion may include not only the seal lip portion 55 and the friction-reducing portion 34, but also the auxiliary lip portion 57.

The friction-reducing portion 34 includes a solid lubricant layer 34a disposed adjacent to the sliding surface 30SS in the radial direction of the rotational axis F0, and a semi-solid lubricant layer 34b disposed closer to the seal lip portion 55 than the solid lubricant layer 34a. As will be described later, the friction-reducing portion 34 may also be configured solely with the solid lubricant layer 34a, without including the semi-solid lubricant layer 34b.

The solid lubricant layer 34a is a coating layer formed on the sliding surface 30SS so as to cover a region of the outer peripheral surface of the connection member 32 where the sealing devices 51A and 51B contact.

The solid lubricant layer 34a serves as a transfer-source supply that supplies a transfer source which reduces friction by transferring it to the sealing devices 51A and 51B that slide in contact with the solid lubricant layer 34a. The term “transfer” refers to a phenomenon in which, during frictional contact between two members, one member is sheared and a portion of its material adheres to the other member.

When a contact portion is sheared during friction, breakage occurs at a location different from the original contact surface, and a small portion of one surface adheres to the opposing surface, and this is referred to as the transfer. The adhered fragment is called a transfer particle. This phenomenon is prominent in adhesive wear. For example, when the surface of a metal is covered with an oxide film or some coating, adhesion and transfer are minimal. However, in a vacuum environment, restoration of the oxide film is suppressed, and adhesion and transfer occur more aggressively. When a particle that has adhered to the opposing surface re-adheres to the original surface, this is referred to as re-transfer. Further, when the transfer particle detaches from the surface, it becomes a wear particle. The solid lubricant layer 34a is formed to have a thickness of 25 μm or more.

The surface roughness of the sliding surface 30SS on which the solid lubricant layer 34a is formed is Rz 1.6 μm or less. It should be noted that the surface roughness of the sliding surface 30SS need only satisfy the above value in at least the region where the solid lubricant layer 34a is formed. Typically, when forming a layer on the sliding surface to reduce friction, for example, the following two methods are employed. The first method involves forming irregularities on the sliding surface to increase the contact area between the sliding surface and the friction-reducing layer. The second method involves performing an embossing process, such as non-directional fine texturing, to improve adhesion between the two layers that slide against each other, thereby reducing friction on the sliding surface.

In contrast, in the embodiment, the sliding surface 30SS on which the solid lubricant layer 34a is formed is subjected in advance to mirror finishing or the like to reduce surface roughness. That is, in the embodiment, the embossing process is performed onto the sliding surface 30SS. As will be described later, this mirror finishing is carried out to promote transfer from the transfer source by smoothing the sliding surface 30SS. The surface roughness of the sliding surface 30SS on which the solid lubricant layer 34a is formed may be Rz 1.6 μm or less.

The hardness of the sliding surface 30SS on which the solid lubricant layer 34a is formed is Vickers hardness (HV) 544 or higher. In other words, the hardness of the sliding surface 30SS on which the solid lubricant layer 34a is formed is Rockwell hardness (HRC) 52 or higher. To achieve the above hardness value for the sliding surface 30SS, it is preferable that the connection member 32 be formed from a stainless-based nitrided steel, a chromium-molybdenum steel, or a carbon steel. Specific examples include nitrided stainless steels such as SUS440C and SUS316L, and carbon steels such as SCM440C, S45C, and S55C.

The solid lubricant layer 34a includes at least a solid lubricant that serves as the transfer source. The solid lubricant may be polytetrafluoroethylene (PTFE). The solid lubricant included in the solid lubricant layer 34a has a particle size of 10 μm or less. If the particle size of the solid lubricant exceeds this value, there is an increased risk of vacuum leakage when solid lubricant particles with large diameters enter the sealing portion, which is undesirable. Accordingly, the particle size of the solid lubricant is set to the above value so as not to impair the sealing performance.

By setting the particle size of the solid lubricant to the above value, it becomes possible to actively generate the transfer particles from the solid lubricant layer 34a. At the same time, the lubricant in the form of the transfer particles can easily adhere to sealing devices 51A and 51B. The term “transfer particles” here refers to particles that are generated from the solid lubricant layer 34a and adhere to the seal lip portion 55 and the auxiliary lip portion 57. Furthermore, by setting the particle size of the solid lubricant to the above value, the lubricant transferred to the sealing devices 51A and 51B as the transfer particles can effectively reduce the coefficient of friction between the sealing devices 51A and 51B and the solid lubricant layer 34a.

The solid lubricant layer 34a is a PTFE coating. Accordingly, even when it is exposed to the vacuum-side space V, it does not contaminate the environment. Here, the use of PTFE in vacuum atmospheres, high vacuum atmospheres, and ultra-high vacuum atmospheres is well known in the art. In addition, the use of PTFE in contact and sliding applications with rubber (polymeric materials) is also well known in the art. The solid lubricant layer 34a may contain polytetrafluoroethylene and polyamide-imide.

The semi-solid lubricant layer 34b is a layer formed by applying a semi-solid lubricant, such as a grease composition. The semi-solid lubricant layer 34b can be applied so as to cover at least the regions of the surface of the solid lubricant layer 34a that contact with the sealing devices 51A and 51B. Alternatively, the semi-solid lubricant layer 34b may be formed over the entire surface of the solid lubricant layer 34a. Further, the semi-solid lubricant layer 34b may be applied so as to cover at least the regions of the sealing devices 51A and 51B that are in contact with the solid lubricant layer 34a.

The semi-solid lubricant layer 34b may be formed of a fluorine grease composition mainly composed of polytetrafluoroethylene (PTFE) and perfluoropolyether (PFPE). For example, the semi-solid lubricant layer 34b may contain PTFE resin powder, tetrafluoroethylene-hexafluoropropylene copolymer (FEP) powder, and perfluoroalkylene resin powder, and the like. The fluorinated grease composition forming the semi-solid lubricant layer 34b may include a fluorinated base oil blended with a thickening agent.

The semi-solid lubricant layer 34b is configured such that the consistency of the semi-solid lubricant corresponds to NLGI Grade No. 1 (325±15) to No. 3 (235±15). The semi-solid lubricant layer 34b may be configured such that the consistency of the semi-solid lubricant corresponds to NLGI Grade No. 2 (280±15). The NLGI (National Lubricating Grease Institute) consistency number conforms to the JIS consistency number. If the consistency of the semi-solid lubricant is higher or softer) than the above value, sealing and assembly performances may deteriorate. Conversely, if the consistency is lower (i.e., harder) than the above range, sliding torque at the sealing portion may increase, potentially resulting in excessive heat generation. When the seal lip portion 55 is formed of a rubber material, excessive temperature rise at the sealing portion may cause degradation of the rubber material, thereby impairing sealing performance, which is undesirable.

The following describes the reduction in friction coefficient achieved through the transfer.

By sliding contact between the sealing portions, which are the sealing devices 51A and 51B and the solid lubricant layer 34a, particles can be actively generated from the solid lubricant layer 34a and the generated particles adhere to the sealing member. In this manner, particles generated from the friction-reducing portion 34 due to friction are transferred to the sealing devices 51A and 51B. Since the transfer particles are solid lubricants originally included in the solid lubricant layer 34a, it becomes possible to reduce the friction coefficient as if the solid lubricant layer 34a were formed directly on the surfaces of sealing devices 51A and 51B.

When the solid lubricant is polytetrafluoroethylene (PTFE), it is necessary to apply the PTFE together with a binder agent onto the surfaces of the sealing devices 51A and 51B and perform a baking process in order to form a friction-reducing layer. However, since the seal lip portion 55 is made of a resin such as rubber, it cannot withstand the baking temperature. Therefore, conventionally, it was not possible to form the solid lubricant layer 34a on the surfaces of the sealing devices 51A and 51B, and thus the above friction-reducing effect could not be achieved.

Whereas in the embodiment, the solid lubricant layer 34a includes the solid lubricant that serves as the transfer source for transfer particles in advance, thereby enabling active generation of the transfer particles from the solid lubricant layer 34a. At the same time, by using this lubricant as the transfer particles, a state in which the solid lubricant adheres to the sealing devices 51A and 51B is actively established. The lubricant transferred to the sealing devices 51A and 51B as the transfer particles can reduce the coefficient of friction between the sealing devices 51A and 51B and the solid lubricant layer 34a. In addition, in the embodiment, the seal lip portion 55 is radially inwardly pressed by the garter spring 58 and the seal lip portion 55 presses the solid lubricant layer 34a, which promotes the transfer of the transfer particles from the solid lubricant layer 34a.

Furthermore, by reducing the coefficient of friction at the sealing portion, the sliding torque can be decreased. Reduction in the coefficient of friction at the sealing portion also enables suppression of heat generation at the sealing portion. By suppressing the heat generation, degradation of rubber materials such as the seal lip portion 55 due to elevated temperatures can be prevented. Additionally, reduction in the coefficient of friction at the sealing portion can prevent wear of the rubber materials of such as the seal lip portion 55. As a result, the service life of the rotary feedthrough 10 can be extended while maintaining vacuum sealing performance.

Typically, particles generated by wear are regarded as contamination sources for the vacuum-side space V and are therefore undesirable. Whereas, in the embodiment, even when transfer particles are actively generated from the solid lubricant layer 34a, these transfer particles adhere to the sealing devices 51A and 51B as the solid lubricants and do not diffuse into the vacuum-side space V. Accordingly, particle contamination of the vacuum-side space V can be sufficiently suppressed.

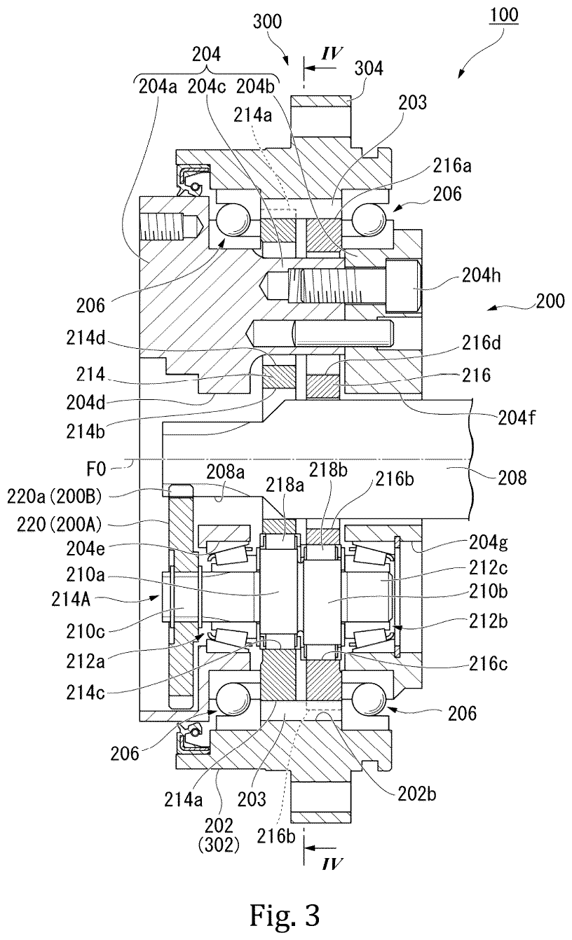

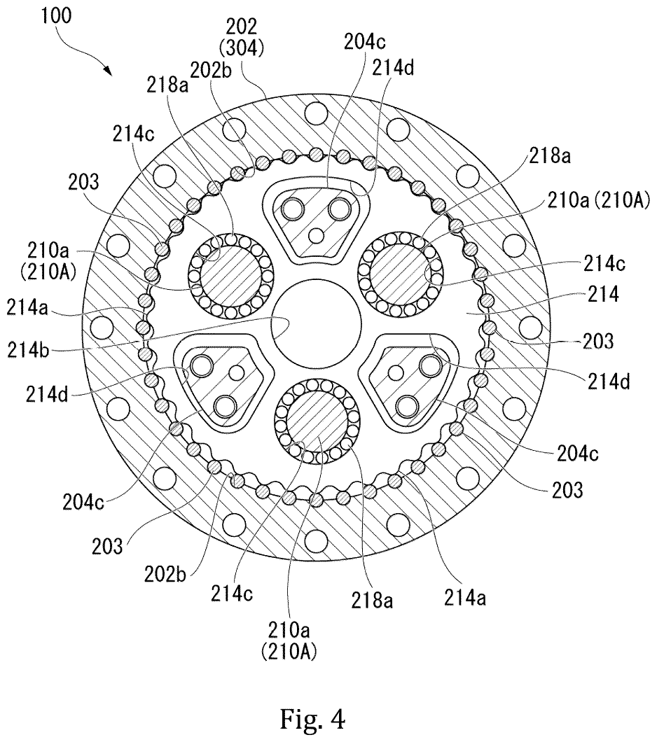

FIG. 3 is a schematic sectional view of the rotation input unit 100 according to the embodiment. FIG. 4 is a cross-sectional view taken along line IV-IV in FIG. 3. The rotation input unit 100 of the embodiment is configured as an eccentric oscillating speed reducer. As shown in FIGS. 3 and 4, the rotation input unit 100 includes a case 300 and a reduction mechanism 200. The case 300 includes a main body 302 and a case flange portion 304. The case flange portion 304 protrudes radially outward from the main body 302 and is connected to the seal partition wall 20.

In the embodiment, the direction along the rotational axis F0 of the main body 302 may be referred to simply an axial direction. The direction intersecting the rotational axis F0 when viewed in the axial direction is hereunder referred to as a radial direction. The direction extending around the rotational axis F0 is referred to as a circumferential direction. The position of the region in the vicinity of the atmosphere-side space A and in which a drive source such as a motor is connected to the speed reducer 100 is referred to as an input side. The position of the region in the vicinity of the vacuum-side space V and in which the output from the speed reducer 100 is received is referred to as an output side. The speed reducer 100 is configured to transmit a rotational driving force while changing the number of rotations at a predetermined ratio between the drive source and the rotating member 30.

The main body 302 is shaped like a cylinder extending along the rotational axis F0. The output side of the main body portion 302 is open in the axial direction, forming an opening. The reduction mechanism 200 is rotatably housed in the opening of the main body 302. The case flange portion 304 is integrally formed on the input side of the main body 302 in the axial direction. On the output side of the speed reducer 100, multiple (e.g., three) transmission gears 200A and an input gear 200B are exposed.

In the speed reducer 100, a crank shaft 210A is rotated by rotating an input shaft 208 corresponding to the input gear 200B, and oscillating gears 214 and 216 oscillatorily rotate in conjunction with eccentric portions 210a and 210b of the crank shaft 210A. In this way, the speed reducer 100 can reduce rotation input thereto and output the reduced rotation.

As shown in FIGS. 3 and 4, the speed reducer 100 of the embodiment includes an outer cylinder 202 corresponding to the main body 302, the carrier 204, the input shaft 208; a plurality of (e.g., three) crank shafts 210A, the first oscillating gear 214, the second oscillating gear 216, and a plurality of (e.g., three) transmission gears 220. The transmission gears 220 correspond to the transmission gears 200A.

The outer cylinder 202 forms the outer surface of the speed reducer 100. The outer cylinder 202 has a substantially cylindrical shape. The outer cylinder 202 has on the inner circumferential surface thereof a plurality of pin grooves 202b. The pin grooves each extend in the axial direction of the outer cylinder 202. Each of the pin grooves 202b has a semicircular sectional shape when cut along a plane orthogonal to the axial direction. The pin grooves 202b are arranged at regular intervals in the circumferential direction along the inner circumferential surface of the outer cylinder 202.

The outer cylinder 202 has a plurality of internal tooth pins 203. The internal tooth pins 203 are each attached in the corresponding pin grooves 202b. Specifically, each of the plurality of internal tooth pins 203 is individually fitted into the corresponding pin groove 202b in a one-to-one manner. Each of the internal tooth pins 203 is oriented to extend in the axial direction of the outer cylinder 202. In this manner, the plurality of internal tooth pins 203 are arranged at regular intervals along the circumference of the outer cylinder 202. The internal tooth pins 203 mesh with first external teeth 214a of the first oscillating gear 214 and second external teeth 216a of the second oscillating gear 216.

The carrier 204 is housed in the outer cylinder 202. The carrier 204 and the outer cylinder 202 are coaxially disposed. The carrier 204 is rotatable relative to the external cylinder 202 (case 300) about the same axis. More specifically, the carrier 204 is disposed on the radially inner side of the outer cylinder 202. The carrier 204 is supported such that it is rotatable relative to the outer cylinder 202. The carrier 204 is supported by a pair of main bearings 206, which are spaced away from each other in the axial direction.

The carrier 204 includes a base portion and an end plate portion 204b. The base portion includes a substrate portion 204a and a plurality of shaft portions 204c (e.g., three).

The base plate portion 204a is disposed inside the outer cylinder 202 near one of the two ends of the outer cylinder 202 in the axial direction. The base plate portion 204a has a circular through-hole 204d at the radially central region. Around the through-hole 204d, a plurality of crank shaft mounting holes 204e are provided at equal intervals in the circumferential direction. The number of crank shaft mounting holes 204e is, for example, three. Hereinafter, the crank shaft mounting holes 204e may simply be referred to as mounting holes 204e.

The end plate portion 204b is disposed apart from the base plate portion 204a in the axial direction. The end plate portion 204a is disposed inside the outer cylinder 202 near the other of the two ends of the outer cylinder 202 in the axial direction. A through-hole 204f is provided at the radially central region of the end plate portion 204b. Around the through-hole 204f, a plurality of crank shaft mounting holes 204g are provided at positions corresponding one-to-one with the plurality of mounting holes 204e in the base plate portion 204a. The number of crank shaft mounting holes 204g is, for example, three. Hereinafter, the crank shaft mounting holes 204g may simply be referred to as mounting holes 204g. Inside the outer cylinder 202, a closed space is formed, which is defined by the inner surface of the end plate portion 204b facing the base plate portion 204a, the inner surface of the base plate portion 204a facing the end plate portion 204b, and the inner circumferential surface of the outer cylinder 202.

The three shaft portions 24 are provided integrally with the base plate portion 21. The three shaft portions 204c extend linearly from the inner surface of the substrate portion 204a toward the end plate portion 204b facing the substrate portion 204a. The three shaft portions 204c are arranged at regular intervals in the circumferential direction (see FIG. 4). The three shaft portions 204c are each fastened to the end plate portion 204b with bolts 204h (see FIG. 3). In this manner, the base plate portion 204a, the shaft portions 204c, and the end plate portion 204b together constitute a single integral piece.

The input shaft 208 receives the driving force from the motor serving as the drive source. The input shaft 208 serves as an input portion. The input shaft 208 is inserted in the through-hole 204f of the end plate portion 204b. The input shaft 208 is also inserted in the through-hole 204d of the base plate portion 204a. The central axis of the input shaft 208 coincides with the rotational axis F0 of the outer cylinder 202 and the carrier 204. The input shaft 208 rotates about the rotational axis F0. An input gear 208a is provided on the outer circumferential surface of the input shaft 208a at the tip portion thereof.

The three crank shafts 210A are arranged around the input shaft 208 inside the outer cylinder 202. The three crank shafts 210A are disposed at equal intervals in the circumferential direction (see FIG. 4). Each crank shaft axis of the three crank shafts 210A is arranged parallel to the rotational axis F0. In the following description, each of the three crank shafts 210A may simply be referred to as crank shaft 210A. Each crank shaft 210A is rotatable about its crank shaft axis relative to the carrier 204. Each crank shaft 210A is supported by the carrier 204 via a pair of crank shaft bearings: a first crank shaft bearing 212a and a second crank shaft bearing 212b (see FIG. 3).

Specifically, the first crank shaft bearing 212a is disposed along the crank shaft 210A at a predetermined distance from one end of the crank shaft 210A toward the center of the shaft. The first crank shaft bearing 212a is fitted into the mounting hole 204e in the base plate portion 204a. The second crank shaft bearing 212b is disposed at the other end of the crank shaft 210A along its axial direction. The second crank shaft bearing 212b is fitted into the mounting hole 204g in the end plate portion 204b. Thus, the crank shaft 210A is rotatably supported by the base plate portion 204a and the end plate portion 204b.

The crank shaft 210A includes a shaft body 212c, a first eccentric portion 210a, and a second eccentric portion 210b. The first eccentric portion 210a is integrally formed with the shaft body 212c. The second eccentric portion 210b is also integrally formed with the shaft body 212c. The first eccentric portion 210a and the second eccentric portion 210b are disposed between the first crank shaft bearing 212a and the second crank shaft bearing 212b in the direction along the crank shaft axis. The first eccentric portion 210a and the second eccentric portion 210b are arranged in series in the axial direction.

The first eccentric portion 210a has a cylindrical shape with an axis extending along the rotational axis F0. The second eccentric portion 210b also has a cylindrical shape with an axis extending along the rotational axis F0. The first eccentric portion 210a and the second eccentric portion 210b are cylindrical and have the same diameter. The first eccentric portion 210a protrudes radially outward from the shaft body 212c. The second eccentric portion 210b likewise protrudes radially outward from the shaft body 212c. The first eccentric portion 210a is offset from the central axis of the shaft body 212c. The second eccentric portion 210b is also offset from the central axis of the shaft body 212c. Each of the first and second eccentric portions 210a and 210b is eccentrically positioned by a predetermined amount relative to the central axis. The first eccentric portion 210a and the second eccentric portion 210b are arranged with a predetermined phase difference in angular position relative to each other.

The crankshaft 210A includes a fitted portion 210c. The fitted portion 210c is provided at one end of the crankshaft 210A. The fitted portion 210c is provided at an axially outer portion of the crankshaft 210A where is to be fitted in the mounting hole 204e of the substrate portion 204a. A transmission gear 220 is provided on the fitted portion 210c.

It should be noted that the speed reducer 100 of the embodiment is not limited to the examples shown in FIGS. 3 and 4. For example, a configuration referred to as a “reverse arrangement” may be employed. In the case of the reverse arrangement, the crankshaft 210A is arranged in the reverse orientation in the axial direction. At the same time, the fitted portion 210c is disposed in the axially outer portion of the mounting hole 204g in the end plate portion 204b.

The first oscillating gear 214 is disposed in the closed space within the outer tube 202. The first oscillating gear 214 is mounted onto the first eccentric portion 210a of the crankshaft 210A. The first oscillating gear 214 is mounted via a first roller bearing 218a. When the crankshaft 210A rotates and the first eccentric portion 210a eccentrically rotates, the first oscillating gear 214 moves in conjunction with this eccentric rotation. The first oscillating gear 214, which is thus driven in conjunction, oscillates and rotates while meshing with the internal tooth pins 203.

The first oscillating gear 214 has an outer profile slightly smaller than the inner diameter of the outer cylinder 202. The first oscillating gear 214 includes first external teeth 214a, a central through hole 214b, a plurality of (for example, three) first eccentric portion insertion holes 214c, and a plurality of (for example, three) shaft portion insertion holes 214d. The first external teeth 214a are shaped like smooth and continuous waves along the entire circumference of the oscillating gear 214.

The central through hole 214b is formed at the radial center of the first oscillating gear 214. The central through hole 214b receives therein the input shaft 208 with a clearance therebetween.

The three first eccentric portion insertion holes 214c are formed in the first oscillating gear 214. The three first eccentric portion insertion holes 214c are arranged around the central through hole 214b. The three first eccentric portion insertion holes 214c are arranged at equal intervals in the circumferential direction. In the crankshaft 210A, the first eccentric portion 210a is inserted into the first eccentric portion insertion hole 214c. The first eccentric portion 210a is inserted at a position close to the inner wall of the first eccentric portion insertion hole 214c. The first eccentric portion 210a is inserted into the first eccentric portion insertion hole 214c via a first rolling bearing 218a.

The three shaft portion insertion holes 214d are formed in the first oscillating gear 214. The three shaft portion insertion holes 214d are arranged around the central through hole 214b. The three shaft portion insertion holes 214d are arranged at regular intervals in the circumferential direction. The three shaft insertion holes 214d are each positioned at a position between the three first eccentric insertion holes 214c in the circumferential direction. Each of the three shaft portions 204c is inserted into a corresponding shaft portion insertion hole 214d with a clearance.

The second oscillating gear 216 is disposed in the closed space of the outer cylinder 202. The first oscillating gear 216 is mounted onto the crankshaft 210A. The second oscillating gear 216 is mounted onto the second eccentric portion 210b. The second oscillating gear 216 is mounted onto the second eccentric portion 210b via a second roller bearing 218b. The first and second oscillating gears 214 and 216 are arranged in the axial direction so as to correspond to the first and second eccentric portions 210a and 210b. When the crankshaft 210A rotates and the second eccentric portion 210b eccentrically rotates, the second oscillating gear 216 moves in conjunction with this eccentric rotation. The second oscillating gear 216, which is thus driven in conjunction, oscillates and rotates while meshing with the internal tooth pins 203.

The second oscillating gear 216 has an outer profile slightly smaller than the inner diameter of the outer cylinder 202. The second oscillating gear 216 is configured in the same manner as the first oscillating gear 214. Specifically, the second oscillating gear 216 includes second external teeth 216a, a central through hole 216b, a plurality of (for example, three) second eccentric portion insertion holes 216c, and a plurality of (for example, three) shaft portion insertion holes 216d. These are configured in the same manner as the first external teeth 214a, the central through hole 214b, the first eccentric portion insertion holes 214c, and the shaft portion insertion holes 214d so as to correspond to the first oscillating gear 214. In the crankshaft 210A, the second eccentric portion 210b is inserted into the second eccentric portion insertion hole 216c. The second eccentric portion 210b is inserted in the second eccentric portion insertion hole 214c on the inner wall side therein. The second eccentric portion 210b is inserted into the second eccentric portion insertion hole 216c via the second roller bearing 218a.

Each transmission gear 220 transmits the rotation of the input gear 208a to the corresponding one of the crankshafts 210A. The transmission gear 220 is mounted onto the corresponding crankshaft 210A. The transmission gear 220 is attached to one end of the shaft body 212c. The transmission gear 220 is fitted onto the fitted portion 210c. The fitted portion 210c is provided at one end of the shaft body 212c. The transmission gear 220 rotates about the same axis as the crankshaft axis of the crankshaft 210A. The transmission gear 220 rotates integrally with the crankshaft 210A. The transmission gear 220 includes external teeth 220a that mesh with the input gear 208a.

The speed reducer 100 is a gear device configured to transmit a driving force while changing the rotation speed at a predetermined rotation-speed ratio between the drive source and the rotating member 30. The speed reducer 100 may include the reduction mechanism 200. The reduction mechanism 200 includes an eccentric portion, an oscillating gear, a first cylindrical portion, and a second cylindrical portion. The oscillating gear has teeth and an insertion hole into which the eccentric portion is inserted. The first cylindrical portion is configured to be attachable to one of first and second members. The second cylindrical portion is configured to be attachable to one of a first member of a second member. The first cylindrical portion has internal teeth meshing with the teeth of the oscillating gear. The second cylindrical portion is positioned inside the first cylinder in the radial direction while holding the oscillating gear. The first and second cylindrical portions are concentrically arranged and rotatable relative to each other when acted upon by oscillation of the oscillating gear caused by rotation of the eccentric portion.

In the rotary feedthrough 10 of the embodiment, along the rotational axis F0, the rotation input unit 100 and a sealing portion that includes the sealing mechanism 50, and the friction-reducing portion 34 are arranged in this order in the direction from the atmosphere-side space A toward the vacuum-side space V. This arrangement enables the reduction of the coefficient of friction in the sealing portion by means of the transfer particles. In particular, polytetrafluoroethylene, which requires a Firing process, is included in the solid lubrication layer 34a as the solid lubricant and can be transferred to the seal lip portion 55 as the transfer particles. Accordingly, the rotary feedthrough 10 can further reduce the coefficient of friction compared to conventional configurations.

The following describes a method of manufacturing the rotary feedthrough 10 according to the embodiment.

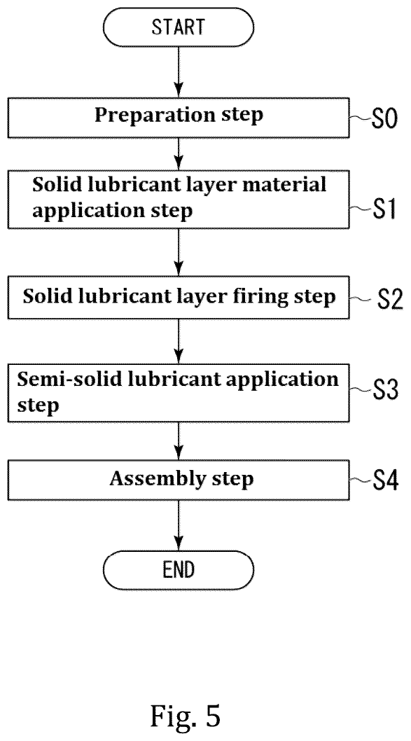

FIG. 5 is a flowchart illustrating the method of manufacturing the rotary feedthrough 10 according to the embodiment. As shown in FIG. 5, the manufacturing method of the rotary feedthrough 10 includes a preparation step S0, a solid lubricant layer material application step S1, a solid lubricant layer firing step S2, a semi-solid lubricant application step S3, and an assembly step S4.

In the preparation step S0, prior to forming the solid lubricant layer 34a, the rotating member 30 having the sliding surface 30SS with the above-described surface roughness is prepared. First, the connection member 32 is formed of a material having the above-mentioned hardness. Next, in the outer peripheral surface 30S of the connection member 32, the region that serves as the sealing portion is defined as the sliding surface 30SS. The outer periphery of the connection member 32 that serves as the sliding surface 30SS is mirror-finished to achieve the above-specified surface roughness. At the same time, as the sealing mechanism 50, the sealing devices 51A are prepared and the number of the sealing devices 51A corresponds to the required number of sealing stages.

In the solid lubricant layer material application step S1, a raw material for forming the solid lubricant layer 34a is applied in a layered manner onto the sliding surface 30SS prepared in the preparation step S0. The solid lubricant layer material may include a solvent, a binder component, and a solid lubricant. Specifically, the solid lubricant layer material is mainly composed of polytetrafluoroethylene (PTFE) and polyamide-imide. As the solid lubricant layer material, a material having the particle size described above is selected.

At this time, the consistency of the solid lubricant layer material may be lower and harder than the consistency of the semi-solid lubricant applied in the semi-solid lubricant application step S3 described later. As for the layer formation on the sliding surface 30SS, the solid lubricant layer material may be applied directly to the sliding surface 30SS. The application method is not particularly limited, and examples include spray coating, dipping, flow coating, dispenser coating, and spin coating. When applying the solid lubricant layer material, the coating thickness of the material is set such that the film thickness of the resulting solid lubricant layer 34a corresponds to the above-described value, taking into account changes due to a following firing process.

In the solid lubricant layer firing step S2, the solid lubricant layer material coating layer formed in the solid lubricant layer material application step S1 is annealed and fired. At this time, the annealing temperature is set within a range of 200° C. to 250° C. The annealing atmosphere may be a vacuum atmosphere, ambient atmosphere, inert gas atmosphere, or nitrogen atmosphere. The annealing process may be performed under atmospheric pressure. Alternatively, the annealing process may be performed under reduced pressure.

By setting the annealing temperature in the solid lubricant layer firing step S2 to the above-mentioned value, the solid lubricant layer material can be fired to form the solid lubricant layer 34a. If the annealing temperature is lower than the above-mentioned value, firing may be insufficient, making it difficult to form the solid lubricant layer 34a, and is therefore undesirable. By setting the annealing temperature to the above-mentioned value, it is possible to prevent change in the hardness of the connection member 32. In particular, if the annealing temperature exceeds the above-mentioned value, the connection member 32 may become annealed, potentially resulting in a decrease in hardness, which is undesirable.

In the semi-solid lubricant application step S3, the semi-solid lubricant is applied to the surface of the solid lubricant layer 34a formed in the solid lubricant layer firing step S2. Alternatively, in the semi-solid lubricant application step S3, the semi-solid lubricant is applied to the surface of the seal lip portion 55. The application method is not particularly limited, and examples include spray coating, dipping, flow coating, dispenser coating, and spin coating. The semi-solid lubricant is a fluorine grease mainly composed of polytetrafluoroethylene (PTFE) and perfluoropolyether.

At this time, the consistency of the semi-solid lubricant may be lower and harder than the consistency of the solid lubricant applied in the solid lubricant layer material application step S1 described later. The consistency of the semi-solid lubricant is set to the above-mentioned value. If the consistency of the semi-solid lubricant is higher or softer than the above-mentioned value, sealing and assembly performances may deteriorate. If the consistency of the semi-solid lubricant is lower or harder than the above-mentioned value, application defects such as coating omission may occur.

In the assembly step S4, the connection member 32 is inserted into the sealing device 51A, and assembly is performed such that the sealing portion exhibits the required sealing performance. Subsequently, other components of the rotary feedthrough 10 are assembled. Thus, the manufacturing of the rotary feedthrough 10 is completed.

In the manufacturing method of the rotary feedthrough according to the embodiment, preparing the connection member 32 with the above-mentioned hardness facilitates achieving the specified surface roughness of the sliding surface 30SS. By setting the surface roughness of the sliding surface 30SS, the adhesion between the solid lubricant layer 34a and the connection member 32 can be improved. Furthermore, by setting the surface roughness of the sliding surface 30SS, it becomes possible to promote the transfer of the solid lubricant in the solid lubricant layer 34a to the seal lip portion 55 as the transfer particles. By forming the above-described solid lubricant layer material coating, the solid lubricant layer 34a capable of reducing the coefficient of friction can be formed. By forming the above-described solid lubricant layer material coating, the solid lubricant layer 34a capable of maintaining vacuum sealing performance can be formed.

In the manufacturing method of the rotary feedthrough according to the embodiment, the annealing temperature for firing the solid lubricant layer material coating is set to the above-mentioned value. This allows sufficient firing of the solid lubricant layer 34a and enables the formation of a PTFE coating capable of reducing the coefficient of friction. By setting the annealing temperature to the above-mentioned value to fire the solid lubricant layer material coating, it is possible to prevent a decrease in the hardness of the connection member 32. By firing the solid lubricant layer 34a on the sliding surface 30SS and not forming the solid lubricant layer which requires firing on the seal lip portion 55, deterioration of the seal lip portion 55 made of rubber and deterioration of the sealing performance can be prevented. Furthermore, by forming the solid lubricant layer 34a on the mirror-finished sliding surface 30SS by firing, wear of the seal lip portion 55 can be prevented.

In the manufacturing method of the rotary feedthrough according to the embodiment, by forming the semi-solid lubricant layer 34b on the surface of the solid lubricant layer 34a, the coefficient of friction in the sealing portion can be further reduced. As described above, forming the semi-solid lubricant layer 34b enables the realization of a predetermined consistency and improves assemblability. By setting the consistency of the semi-solid lubricant layer 34b as described above, sliding torque can be reduced. As also described above, forming the semi-solid lubricant layer 34b makes it possible to further prevent wear of the seal lip portion 55. Moreover, forming the semi-solid lubricant layer 34b as described above enables further suppression of particle generation. In this way, contamination of the vacuum-side space V can be easily prevented.

According to the embodiment, the coefficient of friction in the sealing portion can be reduced. This prevents a temperature rise in the seal lip portion 55 made of rubber, and thereby suppresses the occurrence of blistering in the seal lip portion 55. As a result, the sealing performance of the sealing portion can be easily maintained.

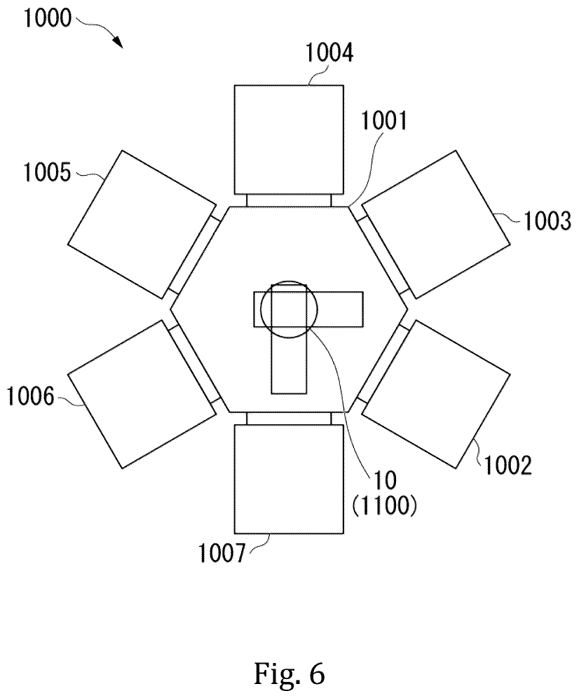

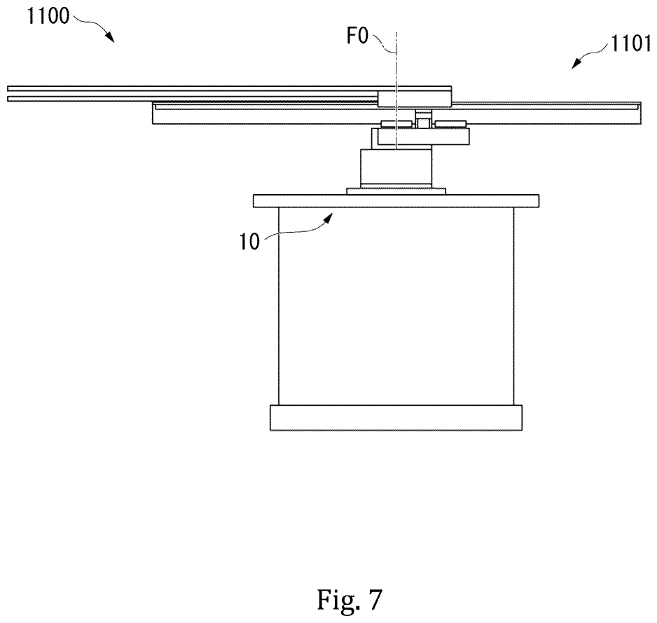

A rotary feedthrough relating to a second embodiment of the disclosure will be described with reference to the accompanying drawings. FIG. 6 is a schematic view showing a vacuum processing apparatus equipped with the rotary feedthrough of the second embodiment. FIG. 7 is a schematic view of a transfer robot having the rotary feedthrough of the embodiment. In the second embodiment, the difference from the above-described first embodiment lies in the arrangement of the rotary feedthrough. Other components corresponding to those in the first embodiment are denoted by the same reference numerals, and their descriptions are omitted.

As shown in FIG. 6, the rotary feedthrough 10 in the embodiment is used in a vacuum processing apparatus 1000. The vacuum processing apparatus 1000 is, for example, used in the manufacture of FPDs, and is capable of processing glass substrates having one side measuring 50 mm or more, 100 mm or more, or even 1000 mm or more. The vacuum processing apparatus 1000 includes a transfer chamber 1001 and a plurality of chambers 1002 to 1007 therearound. The chambers 1002 to 1007 may be, for example, processing chambers for performing predetermined vacuum processes, or load chambers or unload chambers.

The rotary feedthrough 10 of the embodiment is installed in a transfer robot (robot) 1100, which is disposed in the transfer chamber 1001. As shown in FIG. 7, the transport robot 1100 houses the rotary feedthrough 10 in its lower portion and includes, in its upper portion, a transport unit 1101 for conveying glass substrates. The rotary feedthrough 10 rotationally drives the transport unit 1101.

By applying the rotary feedthrough 10 of the embodiment to the substrate transport robot 1100, the coefficient of friction in the sealing portion of the rotary feedthrough 10 can be reduced, thereby significantly extending the service life of the rotary feedthrough 10. At the same time, particle generation from the rotary feedthrough 10 can be suppressed, enabling substantial reduction of contamination in the transfer chamber 1001 and the chambers 1002 to 1007.

The foregoing embodiments disclosed herein describe a plurality of physically separate constituent parts. They may be combined into a single part, and any one of them may be divided into a plurality of physically separate constituent parts. Irrespective of whether or not the constituent parts are integrated, they are acceptable as long as they are configured to attain the object of the invention.

It should be noted that, in the above embodiment, the rotary feedthrough is described as an example of the vacuum actuator, however, the invention is also applicable to mechanisms that introduce a linear driving force into a vacuum environment. In such cases, the friction-reducing portion may be formed so as to include the portion contacted by the sealing member in the axial direction of the shaft member.

To verify the invention, an experiment was conducted to confirm the reduction in the coefficient of friction.

As a test piece corresponding to the rotating member 30 in the sealing portion, a plate made of S45C was prepared. The surface of this test plate was mirror-finished to Rz 1.6 μm to correspond to the sliding surface 30SS. The surface hardness of the test plate was Vickers hardness (HV) 544.

Next, a coating corresponding to the solid lubricant layer 34a was formed on the surface of the test plate. The conditions of formation of the coating at that time are shown below:
Coating liquid composition:
PTFE
Polyamide-imide
PTFE particle size in the coating liquid: 10 μm or less
Firing conditions: Ambient atmosphere
Firing pressure: Atmospheric pressure
Firing temperature: 230° C.
Firing time: 30 minutes
Coating film thickness: 25 μm

Furthermore, grease corresponding to the semi-solid lubricant layer 34b was applied to the surface of this coating. The conditions for the application are as follows:
Grease composition: Base oil: PFPE; Thickener: PTFE
Grease consistency: NLGI Grade No. 2 (280±15)
Grease coating thickness: 50 μm

Next, a rubber ball corresponding to the seal lip portion 55 in the sealing portion was prepared.
Material of rubber ball: Fluororubber
Diameter of rubber ball: R8.5 mm
Hardness of rubber ball: A75

Next, the coating and the rubber ball were slid against each other at a relative speed of 600 mm/s. The applied load during this sliding test corresponded to an average surface pressure of 0.8 MPa. This sliding test was conducted at room temperature.

After a predetermined period had elapsed, the sliding test was terminated, and the coefficient of friction of the coating surface was measured. It was found that the coefficient of friction was reduced by 28% compared to that of a test plate without the coating.

Additionally, the temperature rise on the surface of the test plate was measured before and after the sliding test. It was found that the temperature rise was 2° C. lower than that of the test plate without the coating.

Furthermore, the surface of the test plate was visually inspected after the sliding test. In the case of the test plate without the coating, wear debris from the rubber ball was observed adhering to the surface. Whereas on the test plate with the coating, no visible rubber wear debris was observed.

The surface roughness of the coating was also measured before and after the sliding test. The surface roughness of the coating was approximately Ra 0.31 μm to 0.48 μm and Rz 2.04 μm to 2.58 μm, with almost no change observed before and after the sliding test.

From these results, it is evident that the features of the invention enable a reduction in the coefficient of friction of the seal portion. It is also apparent that heat generation at the seal portion is suppressed. Moreover, it was confirmed that wear of the rubber material can be prevented.

The friction-reducing portion of the present disclosure may serve as the transfer-source supply that supplies a transfer source which reduces friction in the sliding portion by transferring to the sliding sealing member. In this configuration, sliding between the sealing member, which is the sealing portion, and the friction-reducing portion actively generates particles from the friction-reducing portion, and the generated particles are then adhere to the sealing member. Such particles, generated by friction from the friction-reducing portion and transferred to the sealing member, are referred to as the transfer particles. By previously incorporating a lubricant that is intended to become transfer particles into the friction-reducing portion as the transfer source, the transfer particles can be actively generated from the friction-reducing portion. At the same time, by using the lubricant as the transfer particles, the lubricant actively adheres to the sealing member. The lubricant transferred to the sealing member as the transfer particles can reduce the coefficient of friction between the sealing member and the sliding surface.

In this way, the lubricant incorporated in advance into the friction-reducing portion as the transfer source is actively transferred to the sealing member as the transfer particles. Thus, even without applying lubricant directly to the sealing member, the coefficient of friction between the sealing member and the sliding surface can be reduced. This enables prevention of wear of the sealing member.

Moreover, even when the formation of the friction-reducing portion requires thermal processing such as firing and the sealing member is made of a resin material that deteriorates under such thermal treatment, thereby preventing direct formation of the friction-reducing portion on the sealing member, the coefficient of friction in the sealing portion can still be reduced without performing thermal processing. As a result, temperature rise at the sealing portion is avoided, and sealing performance is not compromised. Furthermore, since the lubricant serving as the transfer particles actively transfers to the sealing member, it does not diffuse into the vacuum-side space. Moreover, the sealing member is not worn by the sliding surface, and particle generation from the sealing member is prevented. Therefore, contamination of the vacuum-side space can be effectively prevented.

The friction-reducing portion of the disclosure may be formed on the sliding surface with a thickness of 25 μm or greater. With this configuration, the friction-reducing portion can possess a volume in proportion to the above-mentioned film thickness, thereby allowing it to include the transfer source capable of generating the amount of the transfer particles that sufficiently reduce the coefficient of friction when acting as the lubricant. Accordingly, it becomes possible to generate the transfer particles that transfer to the sealing member as the lubricant and sufficiently reduce the coefficient of friction.

Moreover, by ensuring that the friction-reducing portion has a sufficient film thickness, it is possible to prevent an increase in the coefficient of friction in the sealing portion due to wear of the friction-reducing portion, even when the sealing member slides against it. As a result, the durability of the friction-reducing portion can be improved.

In the disclosure, the surface roughness of the sliding surface on which the friction-reducing portion is formed may be Rz 1.6 μm or less. With this configuration, it becomes easier to actively transfer the lubricant that is incorporated in advance into the friction-reducing portion as the transfer source to the sealing member as the transfer particles. Additionally, the required film thickness of the friction-reducing portion for achieving friction reduction can be minimized.

In the disclosure, the hardness of the sliding surface on which the friction-reducing portion is formed may be Vickers hardness (HV) 544 or greater. With this configuration, the lubricant incorporated into the friction-reducing portion as the transfer source can be actively transferred to the sealing member as the transfer particles. Moreover, the required film thickness of the friction-reducing portion for reducing the coefficient of friction can be minimized. Moreover, by ensuring that the shaft member possesses sufficient hardness, it is possible to prevent wear of the friction-reducing portion even when sliding occurs between the sealing member and the friction-reducing portion, which would otherwise lead to an increase in the coefficient of friction at the sealing portion.

The friction-reducing portion of the disclosure may include the solid lubricant layer including the solid lubricant, and the semi-solid lubricant layer formed between the surface of the solid lubricant layer and the sealing member. With this configuration, the solid lubricant can be incorporated into the solid lubricant layer as the transfer source that supplies the transfer particles, thereby enabling reduction of the coefficient of friction through the transfer particles. In addition, the semi-solid lubricant layer can further reduce the coefficient of friction between the surface of the solid lubricant layer and the sealing member. Accordingly, it is possible to simultaneously achieve the friction coefficient reduction through the solid lubricant acting as the transfer particles and through the semi-solid lubricant layer.

The solid lubricant layer of the disclosure may include the solid lubricant having a particle size of 10 μm or less. With this configuration, the solid lubricant capable of reducing the coefficient of friction can serve as the transfer source for the transfer particles that function as the required lubricant. Thus, the solid lubricant layer can maintain a state in which it includes the solid lubricant that is transferable to the sealing member, and can continuously release the transfer particles from the solid lubricant layer, thereby maintaining a state in which the coefficient of friction can be reduced.

The solid lubricant of the disclosure may include polytetrafluoroethylene (PTFE). With configuration, the transfer particles can sufficiently exhibit its function to reduce the coefficient of friction in the sealing portion. In particular, friction between the sealing member and the surface of the solid lubricant layer can generate a sufficient amount of the solid lubricant as the transfer particles. These transfer particles can be suitably transferred to the sealing member and function as the lubricant. As a result, the coefficient of friction between the sealing member and the surface of the solid lubricant layer can be sufficiently reduced. Moreover, the transfer particles can be prevented from diffusing into the vacuum-side space. Gas emission into the vacuum-side space can also be suppressed.

The shaft member of the disclosure may be formed of nitrided stainless steel, chromium-molybdenum steel, or carbon steel. With this configuration, sufficient hardness of the shaft member can be secured, thereby enabling the friction-reducing portion to release a sufficient amount of the transfer particles. As a result, the coefficient of friction between the sealing member and the sliding surface can be sufficiently reduced. Wear of the sealing member can be prevented, the reduced coefficient of friction at the sliding surface can be maintained, and vacuum sealing performance can be preserved.

The sealing member of the disclosure may include the metal ring that surrounds the outer periphery of the shaft member along the sliding surface, and the seal lip portion that linearly contacts the sliding surface. With this configuration, the seal lip portion of the sealing member can be pressed against the friction-reducing portion, thereby enhancing the sealing performance of the friction-reducing portion and promoting friction reduction through the action of the transfer particles.

Another aspect of the disclosure relates to a method of manufacturing a vacuum actuator, which is the method of manufacturing the above-described vacuum actuator. The method includes a friction-reducing portion formation step in which the friction-reducing portion is formed on the sliding surface; and an assembly step in which the sealing member is assembled so as to contact the sliding surface on which the friction-reducing portion has been formed. In this configuration, a vacuum actuator capable of reducing the coefficient of friction can be manufactured by first forming the friction-reducing portion having predetermined properties and then assembling the sealing member.

The friction-reducing portion formation step may include a preparation step in which the sliding surface on which the friction-reducing portion is to be formed is process to have a surface roughness of Rz 1.6 μm or less. With this configuration, it becomes possible to easily form the friction-reducing portion that can include a lubricant as the transfer source in advance. As a result, the friction-reducing portion capable of actively transferring the transfer particles to the sealing member can be readily formed. Additionally, the coefficient of friction of the friction-reducing portion can be reduced. Furthermore, the required film thickness of the friction-reducing portion for achieving friction reduction can be minimized.

The friction-reducing portion may include a solid lubricant layer including a solid lubricant. The friction-reducing portion formation step may include: a solid lubricant layer material application step of applying a raw material for a solid lubricant layer to the friction-reducing portion; and a solid lubricant layer firing step of firing the applied raw material. Accordingly, the friction-reducing portion formation step forms the friction-reducing portion having the solid lubricant layer including the solid lubricant. With this configuration, the raw material layer that becomes the solid lubricant layer can be readily formed by the application, and the solid lubricant layer can be formed by firing the raw material layer. Thus, it becomes possible to form the friction-reducing portion capable of reducing the coefficient of friction via the transfer, without forming the solid lubricant layer directly on the sealing member. As a result, the friction-reducing portion capable of reducing the coefficient of friction in the sealing portion can be formed without causing thermal degradation of the sealing member.

In the method, the firing temperature in the solid lubricant layer firing step may be in the range of 200° C. to 250° C. With this configuration, a solid lubricant layer containing polytetrafluoroethylene as the solid lubricant can be formed through firing. This allows for hardening of the shaft member made of metal, while preventing annealing-induced reduction in the hardness of the shaft member.

The friction-reducing portion may include a semi-solid lubricant layer formed between the surface of the solid lubricant layer and the sealing member. The friction-reducing portion formation step may include a semi-solid lubricant application step in which the semi-solid lubricant layer is formed between the surface of the solid lubricant layer and the sealing member. The consistency of the semi-solid lubricant layer applied in the semi-solid lubricant application step may be higher than the consistency of the raw material applied in the solid lubricant layer material application step. With this configuration, the coefficient of friction in the sealing portion can be reduced by the solid lubricant layer, and further reduced by the semi-solid lubricant layer. This enables enhanced prevention of wear of the seal member. Moreover, by increasing the consistency of the semi-solid lubricant near the sealing member, heat generation at the sealing portion can be suppressed. At the same time, by lowering the consistency of the solid lubricant layer near the shaft member, workability and assemblability during the vacuum actuator manufacturing can be improved.

What is claimed is:

1. A vacuum actuator comprising:
a partition wall separating a vacuum-side space from an atmosphere-side space;
a shaft member penetrating the partition wall, the shaft member transmitting a drive force;
a sealing member provided on the partition wall, the sealing member sliding against a sliding surface formed on an outer periphery of the shaft member, and the sealing member sealing between the vacuum-side space and the atmosphere-side space; and
a friction-reducing portion formed on the sliding surface.

2. The vacuum of claim 1, wherein the friction-reducing portion serves as a transfer-source supply that supplies a transfer source, the transfer source reducing friction by transferring to the sealing member that slides.

3. The vacuum of claim 2, wherein the friction-reducing portion is formed on the sliding surface with a thickness of 25 μm or greater.

4. The vacuum of claim 2, wherein surface roughness of the sliding surface on which the friction-reducing portion is formed is Rz 1.6 μm or less.

5. The vacuum of claim 2, wherein hardness of the sliding surface on which the friction-reducing portion is formed is Vickers hardness (HV) 544 or greater.

6. The vacuum of claim 2, wherein the friction-reducing portion includes:
a solid lubricant layer including a solid lubricant; and
a semi-solid lubricant layer formed between a surface of the solid lubricant layer and the sealing member.

7. The vacuum of claim 6, wherein the solid lubricant layer includes a solid lubricant having a particle size of 10 μm or less.

8. The vacuum of claim 7, wherein the solid lubricant is formed of polytetrafluoroethylene.

9. The vacuum of claim 5, wherein the shaft member is formed of nitrided stainless steel, chromium-molybdenum steel, or carbon steel.

10. The vacuum of claim 2, wherein the sealing member includes:
a metal ring surrounding an outer periphery of the shaft member along the sliding surface, and
a seal lip portion linearly contacting the sliding surface.

11. A method of manufacturing a vacuum actuator, comprising:
a friction-reducing portion formation step of forming a friction-reducing portion on a sliding surface on an outer periphery of an shaft member, the shaft member penetrating a partition wall that separates a vacuum-side space from an atmosphere-side space; and
an assembly step of assembling a sealing member on the partition wall such that the sealing member contacts the sliding surface.

12. The method of claim 11, wherein the friction-reducing portion formation step includes a preparation step of processing the sliding surface on which the friction-reducing portion is to be formed to have a surface roughness of Rz 1.6 μm or less.

13. The method of claim 11, wherein the friction-reducing portion formation step includes:
a solid lubricant layer material application step of applying a raw material for a solid lubricant layer to the friction-reducing portion; and
a solid lubricant layer firing step of firing the applied raw material, and wherein
the friction-reducing portion formation step forms the friction-reducing portion having the solid lubricant layer including the solid lubricant.

14. The method of claim 13, wherein a firing temperature in the solid lubricant layer firing step is in the range of 200° C. to 250° C.

15. The method of claim 13, wherein the friction-reducing portion formation step includes:
a semi-solid lubricant application step of forming a semi-solid lubricant layer between a surface of the solid lubricant layer and the sealing member,
wherein a consistency of the semi-solid lubricant layer applied in the semi-solid lubricant application step is higher than a consistency of the raw material of the solid lubricant layer applied in the solid lubricant layer material application step.

16. A rotary feedthrough comprising:
a partition wall separating a vacuum-side space from an atmosphere-side space;
a shaft member penetrating the partition wall, the shaft member transmitting a drive force;
an input unit disposed in the atmosphere-side space and configured to input a drive force to the shaft member;
a sealing member provided on the partition wall, the sealing member sliding against a sliding surface formed on an outer periphery of the shaft member, and the sealing member sealing between the vacuum-side space and the atmosphere-side space; and
a friction-reducing portion formed on the sliding surface,
wherein the friction-reducing portion serves as a transfer-source supply that supplies a transfer source, the transfer source reduces friction by transferring to the sealing member that slides,
wherein the friction-reducing portion includes:
a solid lubricant layer including a solid lubricant; and
a semi-solid lubricant layer formed between a surface of the solid lubricant layer and the sealing member,
wherein the input unit outputs, to the shaft member, rotation of a drive source that is disposed in the atmosphere-side space and generates a rotational force, and
wherein the shaft member transmits a rotational drive force to the vacuum-side space.
